(19) United States
(12) Patent Application Publication
(10) Pub. No.: US 2026/0068717 A1
(43) Pub. Date: Mar. 5, 2026

(54) SEMICONDUCTOR PACKAGE INCLUDING A BRIDGE DIE AND MANUFACTURING METHOD THEREOF

(71) Applicant: SAMSUNG ELECTRONICS CO., LTD., SUWON-SI (KR)

(72) Inventors: Jong Youn KIM, Suwon-si (KR); Myeong Han BAE, Suwon-si (KR); Min Jun BAE, Suwon-si (KR); Sang Kyu LEE, Suwon-si (KR)

(21) Appl. No.: 19/225,501

(22) Filed: Jun. 2, 2025

(30) Foreign Application Priority Data
Aug. 29, 2024 (KR) 10-2024-0117052

(51) Int. Cl. H01L 23/538; H01L 21/48; H01L 21/56; H01L 21/683; H01L 21/78; H01L 23/00; H01L 23/31; H01L 23/367; H01L 23/498; H01L 25/16; H10B 80/00; H10D 80/30

(52) U.S. Cl. CPC H01L 23/5386; H10B 80/00; H10D 80/30

(57) ABSTRACT

A semiconductor package includes a first redistribution layer which includes a first face and a second face that are opposite to each other in a first direction, a first semiconductor chip on the second face, a second semiconductor chip on the second face a first mold film on the second face, and that covers the first semiconductor chip and the second semiconductor chip, and a bridge die disposed on the first face, and that electrically connects the first semiconductor chip and the second semiconductor chip, wherein the bridge die is covered with a second mold film.

### CROSS-REFERENCE TO RELATED APPLICATION

This application claims priority under 35 U.S.C. 119 from Korean Patent Application No. 10-2024-0117052, filed on Aug. 29, 2024, in the Korean Intellectual Property Office, the contents of which are herein incorporated by reference in their entirety.

### BACKGROUND

### 1. Technical Field

The present disclosure relates to a semiconductor package including a bridge die and a manufacturing method thereof.

### 2. Discussion of Related Art

With the advancement of wafer fabrication processes and an increase in the size of semiconductor chips, a chiplet technique of separating and manufacturing semiconductor chips for different nodes or different functions has improved wafer yield.

In the chiplet technique, a UCIe (Universal chiplet Interconnect Express) may be used for an interface between the semiconductor chips, and a bridge die may be used as the UCIe.

### SUMMARY

Aspects of the present disclosure provide a semiconductor package including a bridge die in which a crack risk may be reduced or eliminated.

Aspects of the present disclosure also provide a method for manufacturing a semiconductor package including a bridge die, which may reduce or eliminate a crack risk.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising a first redistribution layer which includes a first face and a second face that are opposite to each other in a first direction, a first semiconductor chip on the second face of the first redistribution layer, a second semiconductor chip on the second face of the first redistribution layer, a first mold film on the second face of the first redistribution layer, and that covers the first semiconductor chip and the second semiconductor chip, and a bridge die disposed on the first face of the first redistribution layer, and that electrically connects the first semiconductor chip and the second semiconductor chip, wherein the bridge die is covered with a second mold film.

According to an aspect of the present disclosure, there is provided a semiconductor package comprising a first redistribution layer which includes a first face and a second face that are opposite each other in a first direction, a second redistribution layer which is disposed apart from the first redistribution layer in the first direction, and includes a third face that faces the second face, and a fourth face that is opposite to the third face from each other in the first direction, a first semiconductor chip and a second semiconductor chip disposed between the first redistribution layer and the second redistribution layer, a plurality of molding vias disposed between the first redistribution layer and the second redistribution layer and that extend in the first direction, a first sub-semiconductor package disposed on the second redistribution layer, and a bridge die disposed on the first face, and that electrically connects the first semiconductor chip and the second semiconductor chip, wherein at least a part of a surface of the bridge die is covered with a mold film.

According to an aspect of the present disclosure, there is provided a semiconductor package comprising a first redistribution layer which includes a first face and a second face that are opposite to each other in a first direction, a first semiconductor chip on the second face of the first redistribution layer, a second semiconductor chip on the second face of the first redistribution layer, a first mold film on the second face of the first redistribution layer, and that covers the first semiconductor chip and the second semiconductor chip, and a bridge die disposed on the first face of the first redistribution layer, and that electrically connects the first semiconductor chip and the second semiconductor chip, wherein the bridge die includes, a third face that faces the first face, a fourth face that is opposite to the third face in the first direction, a fifth face and a sixth face that are opposite to each other in the second direction, and a seventh face and an eighth face that are opposite to each other in a third direction intersecting the first direction and the second direction, and wherein the fourth face to the eighth face is covered with a second mold film.

According to an aspect of the present disclosure, there is provided a method for manufacturing a semiconductor package, the method comprising providing a first carrier substrate, forming a first redistribution layer, which includes a first face and a second face that are opposite to each other in a first direction, on the first carrier substrate, disposing a first semiconductor chip and a second semiconductor chip on the second face of the first redistribution layer, forming a first mold film, which covers the first semiconductor chip and the second semiconductor chip on the first redistribution layer, removing the first carrier substrate, attaching a connecting terminal onto the first face of the first redistribution layer, providing a bridge die in which at least one surface is covered with a second mold film, bonding the bridge die onto the first face of the first redistribution layer, and performing a reflow process to connect the connecting terminal and the bridge die to the first redistribution layer.

For example, wherein providing the bridge die includes, providing the bridge die formed on a wafer, providing a second carrier substrate to which a reconstruction tape is attached, mounting the bridge die onto the second carrier substrate such that a third face of the bridge die faces the second carrier substrate, forming the second mold film on the second carrier substrate which covers the bridge die, performing a grinding process on the second mold film to remove a portion of the second mold film on a fourth face of the bridge die opposite the third face, removing the second carrier substrate and the reconstruction tape from the bridge die, and mounting a third carrier substrate on the second mold film covering the bridge die, and attaching a connecting member to the third face of the bridge die, wherein the connecting member of the bridge die is bonded onto the first face of the first redistribution layer.

For example, wherein providing the bridge die includes, attaching a connecting member to a third face of the bridge die, performing a sawing process to separate a plurality of bridge dies, including the bridge die, formed on a wafer, providing a second carrier substrate to which a reconstruction tape is attached, mounting the bridge die onto the second carrier substrate such that the third face of the bridge die faces the second carrier substrate, forming the second mold film which covers the bridge die on the second carrier substrate, attaching a dicing tape to the second mold film, removing the second carrier substrate and the reconstruction tape, and performing the sawing process to separate the bridge die from the plurality of bridge dies.

For example, the method further comprising disposing a plurality of molding vias on the first redistribution layer, forming the first mold film, which covers the plurality of molding vias on the first redistribution layer, forming a second redistribution layer on the first mold film; and, disposing a heat path block (HPB) on the second redistribution layer.

For example, the method further comprising, disposing a plurality of molding vias on the first redistribution layer, forming the first mold film, which covers the plurality of molding vias on the first redistribution layer, forming a second redistribution layer on the first mold film, disposing a sub-semiconductor package on the second redistribution layer, wherein the sub-semiconductor package includes a package substrate, a third semiconductor chip on the package substrate, and a connecting member which connects the package substrate and the second redistribution layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view for explaining a semiconductor package according to some embodiments.

FIG. 2 is a cross-sectional view taken along I-I of FIG. 1.

FIG. 3 and FIG. 4 are diagrams for explaining the bridge die of FIG. 2.

FIG. 5 is a flow chart for explaining a method for manufacturing a semiconductor package according to some embodiments.

FIGS. 6 to 17 are intermediate stage diagrams for describing a method for manufacturing the semiconductor package according to some embodiments.

FIG. 18 is a flow chart for explaining a method for manufacturing a bridge die covered with the mold film according to some embodiments.

FIGS. 19 to 26 are intermediate stage diagrams for explaining a method for manufacturing a bridge die covered with the mold film according to some embodiments.

FIG. 27 is a flowchart for explaining a method for manufacturing the bridge die covered with the mold film according to some embodiments.

FIGS. 28 to 35 are intermediate stage diagrams for explaining a method for manufacturing the bridge die covered with the mold film according to some embodiments.

### DETAILED DESCRIPTION

Hereinafter, a semiconductor package and a method for manufacturing the semiconductor package according to some embodiments will be described referring to the accompanying drawings. Embodiments may, however, be provided in different forms and should not be construed as limiting. The same reference numbers indicate the same components throughout the present disclosure. In the accompanying figures, the thickness of layers and regions may be exaggerated for clarity.

According to an embodiment, a semiconductor package may include a redistribution layer and a bridge die provided on a surface of the redistribution layer, wherein the bridge die may be covered by a mold film that may reduce or eliminate a risk of cracks in the bridge die. The bridge die, so protected, may be disposed on the surface of the redistribution layer adjacent to connecting terminals of the semiconductor package.

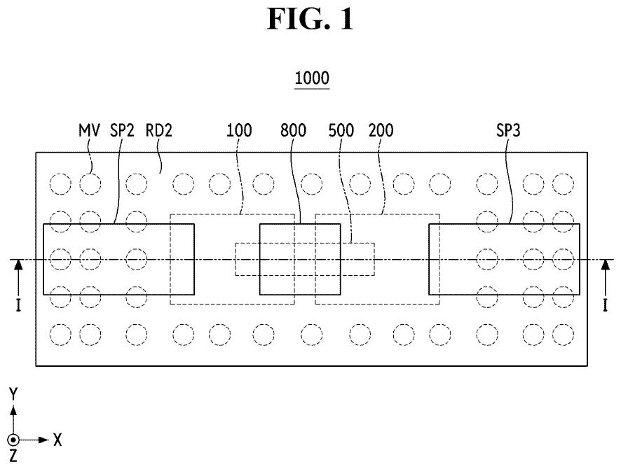

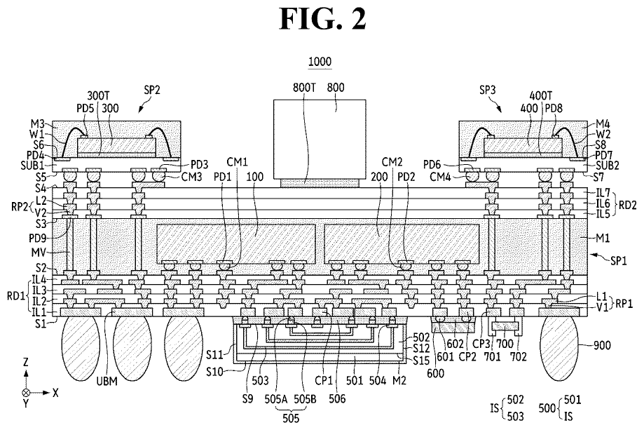

FIG. 1 is a plan view for explaining a semiconductor package according to some embodiments. FIG. 2 is a cross-sectional view taken along I-I of FIG. 1. Hereinafter, a semiconductor package according to some embodiments will be described referring to FIG. 1 and FIG. 2.

Referring to FIG. 1 and FIG. 2, a semiconductor package 1000 may include a first sub-semiconductor package SP1, a second sub-semiconductor package SP2, a third sub-semiconductor package SP3, a bridge die 500, a connecting terminal 900, and a HPB (heat path block) 800.

The first sub-semiconductor package SP1 may include a first redistribution layer RD1, a first semiconductor chip 100, a second semiconductor chip 200, a plurality of molding vias MV, a first mold film M1, a second redistribution layer RD2, the bridge die 500, the connecting terminal 900, and passive elements 600 and 700. The aforementioned configurations of the first sub-semiconductor package SP1 are examples, and according to an embodiment, the first sub-semiconductor package SP1 may include other configurations in addition to the aforementioned configurations.

In the following description, a first direction Z, a second direction X, and a third direction Y may be directions that intersect each other. For example, the first direction Z, the second direction X, and the third direction Y may be directions that are perpendicular to each other. In the following description, an upper part or an upper face may be based on the first direction Z, and a lower part or a lower face may be based on an opposite direction to the first direction Z.

The first redistribution layer RD1 may include a first face S1 and a second face S2 that are disposed opposite to each other in the first direction Z. The first face S1 may be the lower face of the first redistribution layer RD1, and the second face S2 may be the upper face of the first redistribution layer RD1. The first redistribution layer RD1 may include redistribution insulating films IL1 to IL4 and first redistribution patterns RP1.

The first redistribution insulating film IL1 may include an insulating polymer or a photoimageable polymer (PID). For example, the photoimageable polymer may include at least one of photoimageable polyimide, polybenzoxazole (PBO), a phenol-based polymer or a benzocyclobutene-based polymer.

The first redistribution insulating film IL1 may be a layer disposed at the lowermost part of a plurality of redistribution insulating films included in the first redistribution layer RD1. An under bump pattern UBM may be disposed on the first redistribution insulating film IL1. For example, an under bump pattern UBM may be disposed in the first redistribution insulating film IL1, and the first redistribution insulating film IL1 and the under bump pattern UBM may be coplanar and may form the first face S1. The under bump pattern UBM may include a conductive material, and may include, for example, copper. A first connecting pattern CP1, a second connecting pattern CP2, and a third connecting pattern CP3 may be disposed on the first redistribution insulating film IL1. Here, the first redistribution insulating film IL1, the under bump pattern UBM, and the first to third connecting patterns CP1 to CP3 may be coplanar and may form the first face S1. The first to third connecting patterns CP1 to CP3 may include a conductive material, for example, copper. Configurations attached to the first face S1 of the first redistribution layer RD1 may be connected to the under bump pattern UBM and the first to third connecting patterns CP1 to CP3 on the first redistribution insulating film IL1. For example, the connecting terminal 900 may be electrically connected to the under bump pattern UBM, and a connecting member 505 may be electrically connected to the first connecting pattern CP1.

A plurality of first redistribution patterns RP1 may be provided. As shown in FIG. 2, each of the first redistribution patterns RP1 may include a first wiring portion L1 and a first via portion V1. The first via portion V1 of the first redistribution pattern RP1 may be disposed inside the first redistribution insulating film IL1. In the present disclosure, a via portion of a certain conductive component may be a portion for vertical connection (e.g., in the first direction Z), and a wiring portion of a certain conductive component may be a portion for a horizontal connection (e.g., the second direction X or the third direction Y). A width of the wiring portion may be greater than a width of the via portion.

The first wiring portion L1 may extend in a direction parallel to the second face S2 of the first redistribution layer RD1. The width of the first wiring portion L1 may be greater than a width of the first via portion V1. The first via portion V1 may be disposed under the first wiring portion L1. The first via portion V1 may be in a form protruding from the lower face of the first wiring portion L1. A width of an uppermost part of the first via portion V1 may be greater than a width of a lowermost part of the first via portion V1. The first redistribution patterns RP1 may include a conductive material. For example, it may include at least one of copper (Cu), tungsten (W), and titanium (Ti).

The first redistribution layer RD1 may further include a second redistribution insulating film IL2, a third redistribution insulating film IL3, and a fourth redistribution insulating film IL4. The first redistribution patterns RP1 may be disposed inside each of the second to fourth redistribution insulating films IL2 to IL4.

In the present disclosure, although the first redistribution layer RD1 is shown to include four redistribution insulating films IL1 to IL4, embodiments are not limited thereto, and the first redistribution layer RD1 may include three or less, or five or more redistribution insulating films with the first redistribution patterns RP1 provided therein.

The first semiconductor chip 100 and the second semiconductor chip 200 may be disposed on the second face S2 of the first redistribution layer RD1. The first semiconductor chip 100 and the second semiconductor chip 200 may be disposed on the second face S2 to be spaced apart from each other in the second direction X. However, embodiments are not limited thereto, and the first semiconductor chip 100 and the second semiconductor chip 200 may be disposed on the second face S2 to be spaced apart from each other in any direction (e.g., the third direction Y) that intersects the first direction Z.

The first semiconductor chip 100 may include a logic chip, a buffer chip, or a system on chip (SOC). For example, the first semiconductor chip 100 may be an application specific integrated circuit (ASIC) chip or an application processor (AP) chip. The first semiconductor chip 100 may include a central processing unit (CPU), a graphic processing unit (GPU), an accelerator chip, or a neuromorphic chip.

Chip pads PD1 may be disposed on the lower face of the first semiconductor chip 100, and a plurality of first connecting members CM1 may be disposed between the lower face of the first semiconductor chip 100 and the second face S2 of the first redistribution layer RD1. The first connecting members CM1 may electrically connect the chip pads PD1 and the first wiring portions L1 disposed on the second face S2 of the first redistribution layer RD1.

Chip pads PD2 may be disposed on the lower face of the second semiconductor chip 200, and a plurality of second connecting members CM2 may be disposed between the lower face of the second semiconductor chip 200 and the second face S2 of the first redistribution layer RD1. The second connecting members CM2 may electrically connect the chip pads PD2 and the first wiring portions L1 disposed on the second face S2 of the first redistribution layer RD1.

The first semiconductor chip 100 and the second semiconductor chip 200 may be semiconductor chiplet dies. Each chiplet may be a modular chip that performs a specific function. For example, a chiplet may be a processor core, a memory block, an I/O driver, or a signal processing unit. A plurality of semiconductor chiplet dies, e.g., the first semiconductor chip 100 and the second semiconductor chip 200, may be a unit that constitutes a semiconductor die including one or more cores. The semiconductor chiplet dies may function as a single semiconductor die. In the present disclosure, the semiconductor chips may be produced as chiplets and each of the chiplets may be packaged, and a production yield of the semiconductor may be improved while production costs may be reduced.

FIG. 2 shows that the first semiconductor chip 100 and the second semiconductor chip 200 may be disposed on the first redistribution layer RD1, but embodiments are not limited thereto, and three or more semiconductor chips may be mounted on the first redistribution layer RD1.

The plurality of molding vias MV may be disposed between the first redistribution layer RD1 and the second redistribution layer RD2. Each of the plurality of molding vias MV may extend in the first direction Z. The plurality of molding vias MV may be disposed to be horizontally spaced apart from the first semiconductor chip 100 and the second semiconductor chip 200, and may be disposed to surround the first semiconductor chip 100 and the second semiconductor chip 200 in a planar view as shown in FIG. 1. The plurality of molding vias MV may penetrate the first mold film M1 to electrically connect the first redistribution layer RD1 and the second redistribution layer RD2. For example, an upper part of the molding via MV may be connected to a connecting pad PD9 disposed on the third face S3 of the second redistribution layer RD2, and a lower part of the molding via MV may be connected to the first wiring portion L1 disposed on the second face S2 of the first wiring layer RD1.

The molding vias MV may have, for example, but are not limited to, a cylindrical post shape or a tapered shape. The molding vias MV may be formed of one of more components disposed in a stack. The molding vias MV may include, for example, but not limited to, tin (Sn), indium (In), bismuth (Bi), antimony (Sb), copper (Cu), silver (Ag), zinc (Zn), or lead (Pb), or combinations thereof.

The first mold film M1 may be disposed on the second face S2 of the first redistribution layer RD1, and may fill a gap between the first redistribution layer RD1 and the second redistribution layer RD2. The first mold film M1 may cover the configurations mounted on the second face S2 of the first redistribution layer RD1, for example, the plurality of molding vias MV, the first semiconductor chip 100, the first semiconductor chip 200, the first connecting members CM1, and the second connecting members CM2. Further, the first mold film M1 may cover the second face S2 of the first redistribution layer RD1 and the third face S3 of the second redistribution layer RD2. The first mold film M1 may have a lower face that is coplanar with the second face S2 of the first redistribution layer RD1, and may have an upper face that is coplanar with the third face S3 of the second redistribution layer RD2. The first mold film M1 may seal a gap between the second face S2 of the first redistribution layer RD1 and the third face S3 of the second redistribution layer RD2. The first mold film M1 may include, for example, an insulating polymer such as an epoxy molding compound (EMC).

The second redistribution layer RD2 may be disposed on the first mold film M1 to be spaced apart from the first redistribution layer RD1 in the first direction Z. The second redistribution layer RD2 may cover the upper face of the first mold film M1. The second redistribution layer RD2 may include a third face S3 and a fourth face S4 that are disposed opposite to each other in the first direction Z. The third face S3 may be a lower face of the second redistribution layer RD2, and the fourth face S4 may be an upper face of the second redistribution layer RD2. The second redistribution layer RD2 may include a fifth redistribution insulating film IL5, a sixth redistribution insulating film IL6, and a seventh redistribution insulating film IL7, and a second redistribution pattern RP2.

The second redistribution layer RD2 may include a fifth redistribution insulating film IL5. The fifth redistribution insulating film IL5 may include an insulating polymer or a photoimageable polymer (PTD). For example, the photoimageable polymer may include at least one of photoimageable polyimide, polybenzoxazole (PBO), a phenol-based polymer or a benzocyclobutene-based polymer.

The fifth redistribution insulating film IL5 may be a layer disposed at the lowermost part of the plurality of redistribution insulating films included in the second redistribution layer RD2. A connecting pad PD9 may be disposed inside the fifth redistribution insulating film IL5. The connecting pad PD9 may include a conductive material, for example, copper. The connecting pad PD9 may be connected to the molding vias MV.

A plurality of second redistribution patterns RP2 may be provided. As shown in FIG. 2, each of the second redistribution patterns RP2 may include a second wiring portion L2 and a second via portion V2. The second via portion V2 of the second redistribution pattern RP2 may be disposed inside the fifth redistribution insulating film IL5.

The second wiring portion L2 may extend in a direction parallel to the fourth face S4 of the second redistribution layer RD2. A width of the second wiring portion L2 may be greater than a width of the second via portion V2. The second via portion V2 may be disposed at the lower part of the second wiring portion L2. The second via portion V2 may be in a form protruding toward the third face S3 of the second redistribution layer RD2. A width of the lowermost part of the second via portion V2 may be smaller than a width of the uppermost part of the second via portion V2. The second redistribution pattern RP2 may include at least one of a conductive material, for example, copper (Cu), tungsten (W), or titanium (Ti).

The second redistribution layer RD2 may further include a sixth redistribution insulating film IL6 and a seventh redistribution insulating film IL7, and each of the sixth and seventh redistribution insulating films IL6 and IL7 may include the second redistribution patterns RP2, like the fifth redistribution insulating film IL5.

In FIG. 2, the second redistribution layer RD2 is shown to include three redistribution insulating films IL5, IL6, and IL7, but embodiments are not limited thereto, and the second redistribution layer RD2 may include two redistribution insulating films or four or more redistribution insulating films with the second redistribution pattern RP2 provided therein.

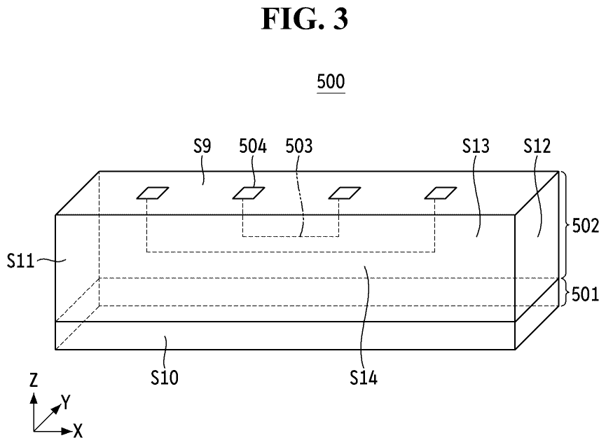

The bridge die 500 may be disposed on the first face S1 of the first redistribution layer RD1. The bridge die 500 may include a nineth face S9 and a tenth face S10 that are opposite to each other in the first direction Z. At this time, the nineth face S9 may be the upper face of the bridge die 500, and the tenth face S10 may be the lower face of the bridge die 500. The bridge die 500 may include a eleventh face S11 and a twelfth face S12 that are disposed opposite to each other in the second direction X. As will be described herein with reference to FIG. 3, the bridge die 500 may include a thirteenth face S13 (shown in FIG. 3) and a fourteenth face S14 (shown in FIG. 3) that are disposed opposite to each other in the third direction Y.

The bridge die 500 may include a substrate 501 and a connecting structure IS. The substrate 501 may be a semiconductor substrate such as a silicon substrate or a silicon carbon substrate. Alternatively, the substrate 501 may be a dielectric substrate such as a silicon oxide substrate. The substrate 501 may include a fifteenth face S15 and a tenth face S10 that are disposed opposite to each other in the first direction Z. The tenth face S10 may be coplanar with the lower face of the bridge die 500.

The connecting structure IS may include a dielectric layer 502 and a metal line 503. The dielectric layer 502 may include inter-metal dielectric (IMD) layers. The metal line 503 may be formed inside the dielectric layer 502. The fifteenth face S15 of the substrate 501 may be covered with the dielectric layer 502. A plurality of connecting pads 504 may be disposed on a nineth face S9 of the bridge die 500. The connecting pads 504 may include metal pads, such as aluminum pads.

A connecting member 505 may be disposed between the bridge die 500 and the first face S1 of the first redistribution layer RD1. For example, the connecting member 505 may include a pillar part 505B that abuts on the connecting pad 504, and a solder part 505A that connects the pillar part 505B to the first connecting pattern CP1 disposed inside the first redistribution insulating film IL1.

A first underfill film 506 may be interposed between the bridge die 500 and the first face S1 of the first redistribution layer RD1. The first underfill film 506 may cover a part of the first face S1 of the first redistribution layer RD1, and may cover the nineth face S9 of the bridge die 500. The first underfill film 506 may also cover the connecting members 505. At least a part of the lower face of the first underfill film 506 may be in contact with the upper face of the second mold film M2. The first underfill film 506 may include, but not limited to, an insulating polymer material such as an EMC.

The bridge die 500 may connect the first semiconductor chip 100 and the second semiconductor chip 200. For example, the bridge die 500 may electrically connect the first connecting member CM1 attached to the lower face of the first semiconductor chip 100 and the second connecting member CM2 attached to the lower face of the second semiconductor chip 200. The bridge die 500 may provide an interface for a signal exchange or the like between the first semiconductor chip 100 and the second semiconductor chip 200. For example, the bridge die 500 may be a semiconductor die that serves as a universal chiplet interconnect express (UCIe) for interface between the first semiconductor chip 100 and the second semiconductor chip 200. According to an embodiment, at least a part of the bridge die 500 may overlap the first semiconductor chip 100 in a planar manner, and at least a part of the bridge die 500 may overlap the second semiconductor chip 200 in a planar manner. According to a fan-out structure of the first redistribution layer RD1, the bridge die 500 may be spaced apart from the first semiconductor chip 100 and/or the second semiconductor chip 200 in a plan view.

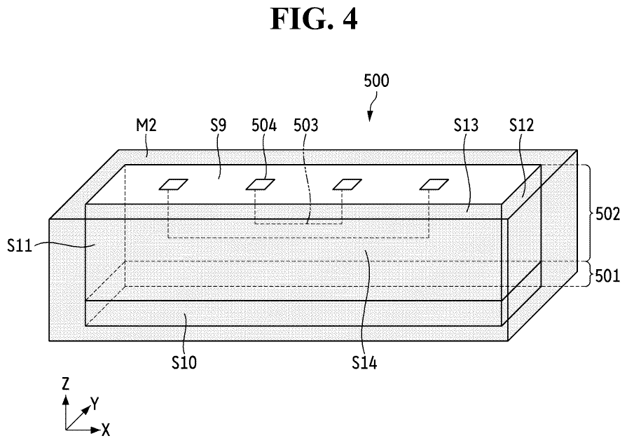

The bridge die 500 may have a hexahedral shape, which may be cuboid. At least one of the remaining five faces of the bridge die 500, except for the nineth face S9, may be covered with the second mold film M2. For example, all the remaining five faces of the bridge die 500, except for the nineth face S9, may be covered with the second mold film M2. The bridge die and the second mold film M2 will be described below in detail referring to FIG. 3 and FIG. 4.

A plurality of connecting terminals 900 may be provided and attached to the first face S1 of the first redistribution layer RD1. The connecting terminals 900 may be bonded to the lower face of the under bump pattern UBM disposed inside the first redistribution insulating film IL1. The connecting terminal 900 may be in contact with the lower face of the under bump pattern UBM. The connecting terminals 900 may be arranged on the first face S1 of the first redistribution layer RD1 and may surround at least a portion of the bridge die 500 and the passive elements 600 and 700. The connecting terminals 900 may include a conductive material, for example, at least one of nickel (Ni), tin (Sn), or silver (Ag). The semiconductor package 1000 may be connected to other external configurations through the connecting terminals 900. For example, the semiconductor package 1000 may send and receive signals to and from an external configuration through the connecting terminal 900.

A passive element 600 may be disposed on the first face S1 of the first redistribution layer RD1. The passive element 600 includes a connecting face that faces the first redistribution layer RD1, and a non-connecting face that is opposite to the connecting face in the first direction Z, and may include a side face between the connecting face and the non-connecting face. Here, the non-connecting face is located on an opposite side to the face that faces the first redistribution layer RD1, and may refer to a face exposed to the outside of the semiconductor package 1000. For example, the connecting face may be the upper face of the passive element 600, and the non-connecting face may be the lower face of the passive element 600.

The passive element 600 may include, for example, a capacitor, an inductor, or beads. For example, the passive element 600 may be a silicon (Si) capacitor in the form of a chip having a high electric capacity. The connecting face of the passive element 600 may include a connecting terminal. The connecting terminal of the passive element 600 is a configuration for electrically connecting the passive element 600 to the configuration of the first redistribution layer RD1, and may include a conductive material. A plurality of connecting members 601 may be provided between the passive element 600 and the first redistribution layer RD1. The lower part of the connecting member 601 may be in contact with the connecting terminal disposed on the connecting face of the passive element 600, and the upper part of the connecting member 601 may be in contact with the second connecting pattern CP2 disposed in the first redistribution insulating film IL1. The connecting member 601 may be electrically connected to the connecting terminal of the passive element 600 and the second connecting pattern CP2.

A second underfill film 602 may be disposed between the passive element 600 and the first redistribution layer RD1, and may be disposed apart from the bridge die 500, the passive element 700, and the connecting terminal 900. The second underfill film 602 may electrically insulate the passive element 600 from the bridge die 500, the passive element 700, and the connecting terminal 900. The second underfill film 602 may cover the entire connecting face of the passive element 600, a part of the first face S1 of the first redistribution layer RD1, and the connecting member 601. The second underfill film 602 may include an insulating resin, for example, an EMC or the like.

The passive element 700 may be disposed on the first face S1 of the first redistribution layer RD1. The passive element 700 may be, for example, a capacitor. For example, the passive element 700 may be a silicon capacitor, a multi-layer ceramic capacitor (MLCT) or a low inductance ceramic capacitor (LOC). However, the present disclosure is not limited thereto.

Each of the first conductive pad 701 and the second conductive pad 702 may be disposed on the first face S1 of the first redistribution layer RD1. Each of the first conductive pad 701 and the second conductive pad 702 may be disposed to protrude from the first face S1 of the first redistribution layer RD1. Each of the first and second conductive pads 701 and 702 may but on the side wall of the passive element 700, and may include a conductive material. For example, each of the first and second conductive pads 701 and 702 may be disposed to be spaced apart from each other in the second direction X.

The first and second conductive pads 701 and 702 may be electrically connected to the third connecting pattern CP3 disposed inside the first redistribution insulating film IL1, and may be electrically connected to the passive element 700. That is, each of the first and second conductive pads 701 and 702 may electrically connect the first redistribution layer RD1 and the passive element 700.

For example, each of the first and second conductive pads 701 and 702 may ground the passive element 700. Furthermore, each of the first and second conductive pads 701 and 702 may supply power to the passive element 700.

The second sub-semiconductor package SP2 may include a first package substrate SUB1, a third semiconductor chip 300, a bonding wire W1, a third mold film M3, and a third connecting member CM3. The first package substrate SUB1 may include a fifth face S5 and a sixth face S6 that are opposite to each other in the first direction Z. The fifth face S5 may be the lower face of the first package substrate SUB1, and the sixth face S6 may be the upper face of the first package substrate SUB1. The first package substrate SUB1 may be a printed circuit board (PCB). When the first package substrate SUB1 is the printed circuit board, the first package substrate SUB1 may be a multilayer circuit board having vias and various circuits therein. A substrate upper pad PD4 may be disposed on the sixth face S6 of the first package substrate SUB1, and a substrate lower pad PD3 may be disposed on the fifth face S5.

The third semiconductor chip 300 may be disposed on the sixth face S6 of the first package substrate SUB1. The third semiconductor chip 300 may be disposed on the first package substrate SUB1 through an adhesive layer 300T. The adhesive layer 300T may be disposed between the first package substrate SUB1 and the third semiconductor chip 300, and may be a die attach film (DAF) including epoxy. The third semiconductor chip 300 may be a volatile memory chip such as a dynamic random access memory (DRAM), but embodiments are not limited thereto. The third semiconductor chip 300 may be connected to the first package substrate SUB1 through a chip pad PD5 disposed on the upper face thereof. For example, the third semiconductor chip 300 and the first package substrate SUB1 may be electrically connected to each other through a bonding wire W1 that connects the chip pad PD5 and the substrate upper pad PD4.

The upper part of the third connecting member CM3 may be in contact with the substrate lower pad PD3, and the lower part of the third connecting member CM3 may be in contact with the second wiring portion L2 disposed on the fourth face S4 of the second redistribution layer RD2. The third connecting member CM3 may electrically connect the first package substrate SUB1 and the second redistribution layer RD2, and may include a conductive material.

The third mold film M3 may be disposed on the first package substrate SUB1, and may cover the sixth face S6 of the first package substrate SUB1, the upper face and the side face of the third semiconductor chip 300, and the bonding wire W1. The third mold film M3 may include an insulating polymer such as an EMC.

The third sub-semiconductor package SP3 may include a configuration similar to the second sub-semiconductor package SP2. For example, the third sub-semiconductor package SP3 may include the second package substrate SUB2, the fourth semiconductor chip 400, the bonding wire W2, the fourth mold film M4, and the fourth connecting member CM4.

The second package substrate SUB2 may include a seventh face S7 and an eighth face S8 that are opposite to each other in the first direction Z. The seventh face S7 may be a lower face of the second package substrate SUB2, and the eighth face S8 may be an upper face of the second package substrate SUB2. The second package substrate SUB2 may be a printed circuit board (PCB). When the second package substrate SUB2 is the printed circuit board, the second package substrate SUB2 may be a multi-layer circuit board having vias and various circuits therein. A substrate upper pad PD7 may be disposed on the eighth face S8 of the second package substrate SUB2, and a substrate lower pad PD6 may be disposed on the seventh face S7.

The fourth semiconductor chip 400 may be disposed on the eighth face S8 of the second package substrate SUB2. The fourth semiconductor chip 400 may be disposed on the second package substrate SUB2 through an adhesive layer 400T. The adhesive layer 400T may be disposed between the second package substrate SUB2 and the fourth semiconductor chip 400, and may be a DAF including epoxy. The fourth semiconductor chip 400 may be a volatile memory chip such as a DRAM, but embodiments are not limited thereto. The fourth semiconductor chip 400 may be connected to the second package substrate SUB2 through a chip pad PD8 disposed on an upper face thereof. For example, the fourth semiconductor chip 400 and the second package substrate SUB2 may be electrically connected through a bonding wire W2 that connects the chip pad PD8 and the substrate upper pad PD7.

The upper part of the fourth connecting member CM4 may be in contact with the substrate lower pad PD6, and the lower part of the fourth connecting member CM4 may be in contact with the second wiring portion L2 disposed on the fourth face S4 of the second redistribution layer RD2. The fourth connecting member CM4 may electrically connect the second package substrate SUB2 and the second redistribution layer RD2 to each other, and may include a conductive material.

The fourth mold film M4 may be disposed on the second package substrate SUB2 and cover the eighth face S8 of the second package substrate SUB2, the upper face and side face of the fourth semiconductor chip 400, and the bonding wire W2. The fourth mold film M4 may include an insulating polymer such as an EMC.

Although FIG. 2 shows that the second and third sub-semiconductor packages SP2 and SP3 each include a DRAM chip, embodiments are not limited thereto. For example, the second or third sub-semiconductor package SP2 or SP3 may include a structure in which the plurality of memory chips are vertically stacked.

Further, although FIG. 2 shows that the second and third sub-semiconductor packages SP2 and SP3 include a wire bonding structure, embodiments are not limited thereto. For example, the second or third sub-semiconductor package SP2 or SP3 may be flip-chip mounted or the second or third sub-semiconductor package SP2 or SP3 may include a structure in which a plurality of memory dies connected by a through silicon via (TSV) structure are vertically stacked.

A HPB 800 may be disposed on the second redistribution layer RD2. The HPB 800 may be disposed at a location of the fourth face S4 of the second redistribution layer RD2 spaced apart from the second wiring portion L2. The HPB 800 may be attached to the second redistribution layer RD2 via a tape 800T. The HPB 800 may serve to emit heat generated in the first semiconductor chip 100 and the second semiconductor chip 200 to the outside of the semiconductor package 1000.

In this way, the semiconductor package 1000 may have a Package On Package (POP) structure in which the first sub-semiconductor package SP1 including a logic chip such as an application processor chip is disposed at the lower part, and the second sub-semiconductor package SP2 and the third sub-semiconductor package PS3 including a memory chip such as a DRAM are stacked vertically on the first sub-semiconductor package SP1. Although FIG. 2 shows that two second and third sub-semiconductor packages SP2 and SP3 are disposed on the first sub-semiconductor package SP1, one sub-semiconductor package may be stacked on the first sub-semiconductor package SP1, or three or more sub-semiconductor packages may be stacked.

FIG. 3 and FIG. 4 are diagrams for explaining the bridge die of FIG. 2.

Referring to FIG. 3 and FIG. 4, the bridge die 500 may include a nineth face S9 and a tenth face S10 that are opposite to each other in the first direction Z, an eleventh face S11 and a twelfth face S12 that are opposite to each other in the second direction X, and a thirteenth face 13 and a fourteenth face 14 that are disposed opposite to each other in the third direction Y. The nineth face S9 and the tenth face S10 may be an upper face and a lower face (bottom face) of the bridge die 500, respectively, and the eleventh face S11 and the twelfth face S12 may be a left face and a right face of the bridge die 500, respectively. The thirteenth face 13 and the fourteenth face 14 may be a back face and a front face of the bridge die 500, respectively. That is, the bridge die 500 may include a hexahedral shape including the nineth to fourteenth faces S9 to S14.

A plurality of connecting pads 504 may be disposed on the nineth face S9 of the bridge die 500, and some of the connecting pads 504 may be pads for being connected to the first semiconductor chip 100 (shown in FIG. 2), and some others of the connecting pads 504 may be pads for being connected to the second semiconductor chip 200 (shown in FIG. 2). The pads among the connecting pads 504 for being connected to the first semiconductor chip 100 may be electrically connected to the pads among the connecting pads 504 for being connecting to the second semiconductor chip 200 through the metal line 503. The plurality of connecting pads 504 may be coplanar with the nineth face S9 of the bridge die 500 or may be disposed on the nineth face S9 to extend in the first direction Z from the nineth face S9.

Although FIG. 3 and FIG. 4 show that four connecting pads 504 are disposed on the nineth face S9 of the bridge die 500, embodiments are not limited thereto, and the number of connecting pads 504 disposed on the nineth face S9 of the bridge die 500 may vary depending on an embodiment. Further, for one of more of the metal lines 503, a portion of the metal line 503 extending in the first direction Z may be replaced by vertical vias, and the vertical vias may be connected by a middle portion of the metal line 503. For example, beginning with a middle instance of the metal lines 503, the vertical vias may become successively taller in the first direction Z. For example, vertical vias adjacent to the eleventh fact S11 and the twelfth face S12 may be taller than vertical vias near a middle portion of the bridge die. Referring to FIG. 2, a middle instance of the metal lines 503 may be replaced by a connecting pad 504, and the connection pad 504 may connect the first semiconductor chip 100 and the second semiconductor chip 200, and may not extend away the nineth face S9. For example, the connection pad 504 may extend between two connecting members 505 connected to the first semiconductor chip 100 and the second semiconductor chip 200, respectively.

Referring to FIG. 4, among the six faces of the bridge die 500, the remaining faces including the tenth through fourteenth faces S10, S11, S12, S13, and S14, except the nineth face S9 that faces the first redistribution layer RD1 (shown in FIG. 2), may be covered with the second mold film M2. That is, the eleventh (left side) face S11, the twelfth (right side) face S12, the fourteenth (front) face S14, the thirteenth (back) face S13, and the tenth (lower) face (bottom face) S10 of the bridge die 500 may be all wrapped with the second mold film M2 and may not be exposed to the outside. In an embodiment, the mold film M2 may cover the nineth face S9, and the mold film M2 may be ground to expose the connecting pads 504 of the bridge die 500.

The eleventh (left side) face S11, the twelfth (right side) face S12, the fourteenth (front) face S14, the thirteenth (back) face S13, and the tenth (lower) face (bottom face) S10 of the bridge die 500 may be coplanar with the eleventh (left side) face S11, the twelfth (right side) face S12, the fourteenth (front) face S14, and the thirteenth (back) face S13 of the dielectric layer 502. As a result, faces of the dielectric layer 502 that are opposite to each other in the second direction X, and faces of the dielectric layer 502 that are opposite to each other in the third direction Y may be covered with the second mold film M2.

Referring to FIG. 2, the bridge die 500 may have a structure which is attached onto the first face S1 of the first redistribution layer RD1 and is exposed to the outside of the semiconductor package 1000. Therefore, the bridge die 500 may have a structure which is vulnerable to external shocks when performing the process of a subsequent process or in the course of mounting the product. According to the present disclosure, the risk of cracks that may occur in the bridge die 500 may be reduced or eliminated by wrapping and protecting the tenth through fourteenth faces S10, S11, S12, S13, and S14 with the second mold film M2. As described herein, the nineth face S9 that faces the first redistribution layer RD1 may be optionally covered or exposed by the second mold film M2. The first underfill film 506 may be formed between the bridge die 500 and the first redistribution layer RD1. For example, the first underfill film 506 may be disposed on the nineth face S9 or the second mold film M2 that covers the nineth face S9.

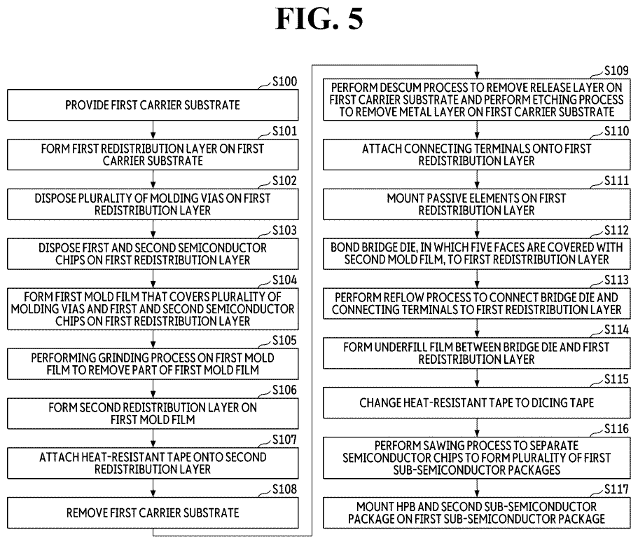

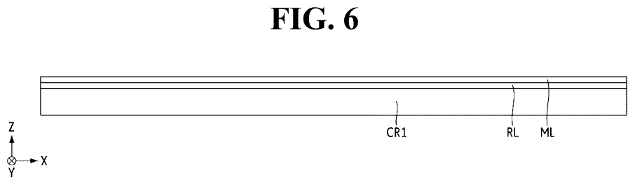

FIG. 5 is a flow chart for explaining a method for manufacturing a semiconductor package according to some embodiments. FIGS. 6 to 17 are intermediate stage diagrams for describing a method for manufacturing the semiconductor package according to some embodiments. Hereinafter, a method for manufacturing the semiconductor package according to some embodiments will be described referring to FIGS. 5 to 17.

Referring to FIG. 5 and FIG. 6, a first carrier substrate CR1 may be provided (S100). The first carrier substrate CR1 may include, but not limited to, silicon, metal, glass, plastic, or ceramic. The first carrier substrate CR1 may be used to support a material when forming the first sub-semiconductor package SP1 (shown in FIG. 2), and may be removed later as necessary.

A release layer RL may be conformally formed on the first carrier substrate CR1. The release layer RL may abut on the first carrier substrate CR1. The release layer RL may include, for example, a photoimageable insulating material. The release layer RL may include, for example, an epoxy or polyimide. However, the technical idea of the present disclosure is not limited thereto. That is, in some other embodiments, the release layer RL may be an inorganic release layer to introduce stable detectable characteristics. In this case, the release layer RL may be, for example, a carbon material, but the technical idea of the present disclosure is not limited thereto.

A metal layer ML may be conformally formed on the release layer RL. The metal layer ML may abut on the release layer RL. The metal layer ML may be selectively removed from the first carrier substrate CR1 and the release layer RL in a subsequent process. The metal layer ML may include, but not limited to, a metal such as titanium (Ti).

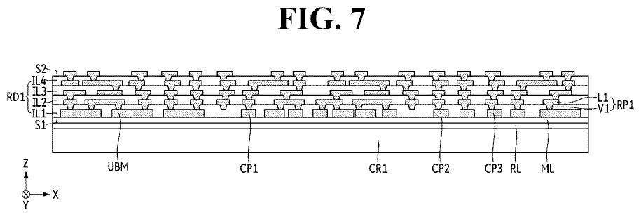

Referring to FIG. 5 and FIG. 7, the first redistribution layer RD1 may be formed on the first carrier substrate CR1 (S101). For example, the first redistribution layer RD1 may be disposed on the first carrier substrate CR1 such that the first face S1 of the first redistribution layer RD1 faces the first carrier substrate CR1 on which the release layer RL and the metal layer ML are formed, and the second face S2 of the first redistribution layer RD1 is opposite to the first carrier substrate CR1.

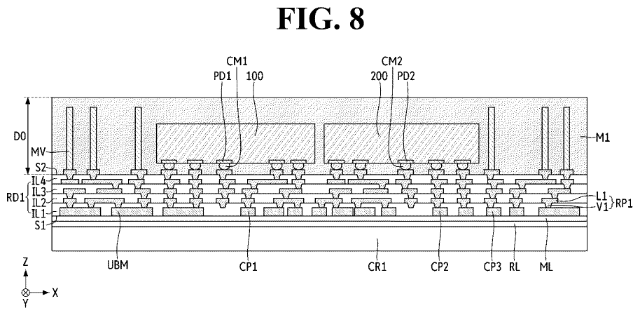

Referring to FIG. 5 and FIG. 8, a plurality of molding vias MV and the first and second semiconductor chips 100 and 200 may be disposed on the first redistribution layer RD1 (S102 and S103). The molding vias MV may be mounted on the first redistribution layer RD1 through the first wiring portion L1 on the second face S2 of the first redistribution layer RD1. Also, the first semiconductor chip 100 may be mounted on the first redistribution layer RD1 through the chip pads PD1 and the first connecting members CM1 disposed on the lower face thereof, and the second semiconductor chip 200 may be mounted on the first redistribution layer RD1 through the chip pads PD2 and the second connecting members CM2 disposed on the lower face thereof.

The first mold film M1 that covers the plurality of molding vias MV and the first and second semiconductor chips 100 and 200 may be formed on the first redistribution layer RD1 (S104). In this case, the first mold film M1 may completely cover the first redistribution layer RD1, the first and second semiconductor chips 100 and 200, the molding vias MV, and the first and second connecting members CM1 and CM2.

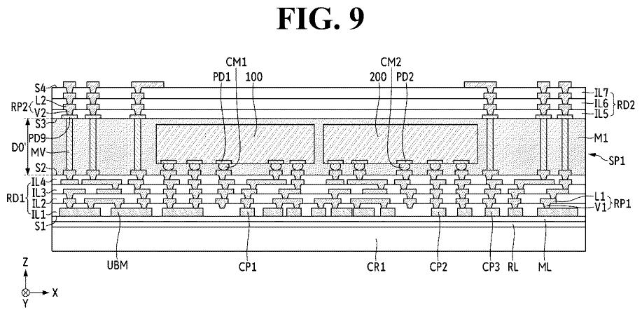

Referring to FIG. 5 and FIG. 9, a grinding process may be performed on the first mold film M1 to remove a part of the first mold film M1 (S105). For example, if the length of the first mold film M1 in the first direction Z before grinding was DO (shown in FIG. 8), the length of the first mold film M1 in the first direction Z after grinding may be DO′ which is smaller than DO.

By grinding at least a part of the upper part of the first mold film M1, the upper faces of the molding vias MV may be exposed. However, the mold film that covers the upper faces of the first and second semiconductor chips 100 and 200 may not be completely removed, and therefore each of the upper faces of the first and second semiconductor chips 100 and 200 may be covered. However, embodiments are not limited thereto. For example, by grinding the first mold film M1, each of the upper faces of the first and second semiconductor chips 100 and 200 may be exposed. However, in the present disclosure, the description will be given assuming a case where, as at least a part of the upper part of the first mold film M1 is ground, the upper faces of the molding vias MV are exposed, and the upper faces of the first and second semiconductor chips 100 and 200 are not exposed. As a result, the upper faces of each of the plurality of molding vias MV and the upper face of the first mold film M1 may be coplanar with each other.

The second redistribution layer RD2 may be formed on the first mold film M1 (S106). For example, the second redistribution layer RD2 may be disposed on the first mold film M1 such that the third face S3 of the second redistribution layer RD2 abuts on the upper face of the first mold film M1, and the fourth face S4 of the second redistribution layer RD2 is opposite to the first mold film MS.

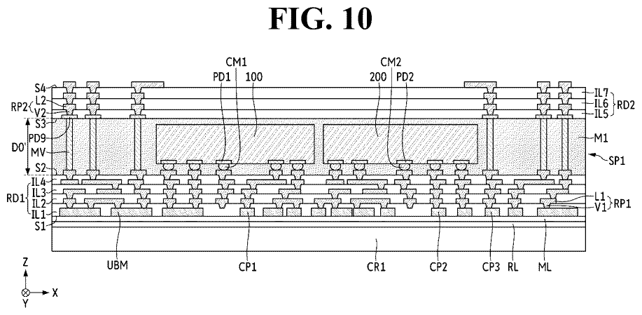

Referring to FIG. 5 and FIG. 10, after providing the heat-resistant tape T1, the semiconductor package manufactured up to step S106 may be turned upside down, and then the heat-resistant tape T1 may be attached onto the second redistribution layer RD2 (S107). For example, as shown in FIG. 10, the heat-resistant tape T1 may be attached onto the fourth face S4 of the second redistribution layer RD2. The heat-resistant tape T1 may include a heat-resistant material for inhibiting or preventing the semiconductor package configuration and materials attached to the heat-resistant tape T1 from shaking, when performing a process in which the semiconductor package is subjected to heat, such as in a reflow process, in a subsequent process.

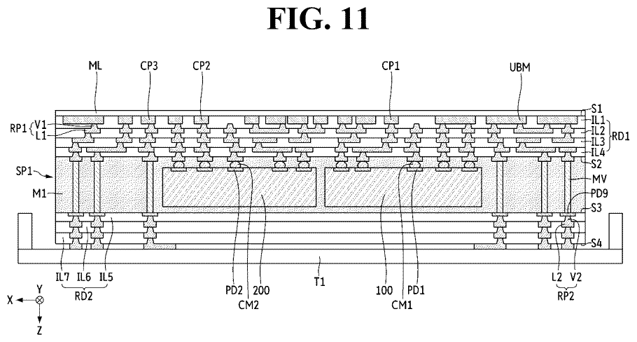

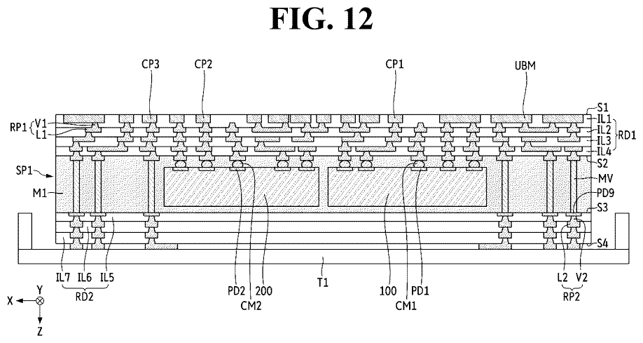

Referring to FIG. 5, FIG. 11 and FIG. 12, the first carrier substrate CR1 may be removed from the first redistribution layer RD1 (S108), and the release layer RL and the metal layer ML may be removed from the first redistribution layer RD1 (S109). For example, the release layer RL on the first carrier substrate CR1 may be removed through a descum process, and the metal layer ML may be removed through an etching process. However, embodiments are not limited thereto, and the first carrier substrate CR1 and the release layer RL may be removed through a laser debonding process.

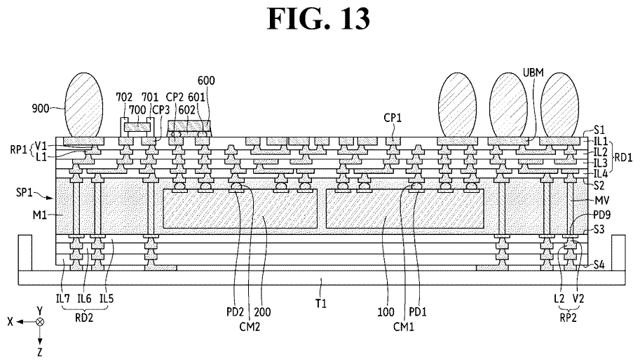

Referring to FIG. 5 and FIG. 13, the connecting terminals 900 may be attached onto the first redistribution layer RD1 (S110), and the passive elements 600 and 700 may be mounted on the first redistribution layer RD1 (S111). For example, the connecting terminal 900 may be attached to the under bump pattern UBM inside the first redistribution insulating film IL1 that is exposed after the first carrier substrate CR1, the release layer RL, and the metal layer ML are removed. Similarly, the connecting members 601 may be attached to the second connecting pattern CP2 inside the first redistribution insulating film IL1 that is exposed after the first carrier substrate CR1, the release layer RL, and the metal layer ML are removed, and the first and second conductive pads 701 and 702 may be attached to the third connecting pattern CP3 inside the exposed first redistribution insulating film IL1.

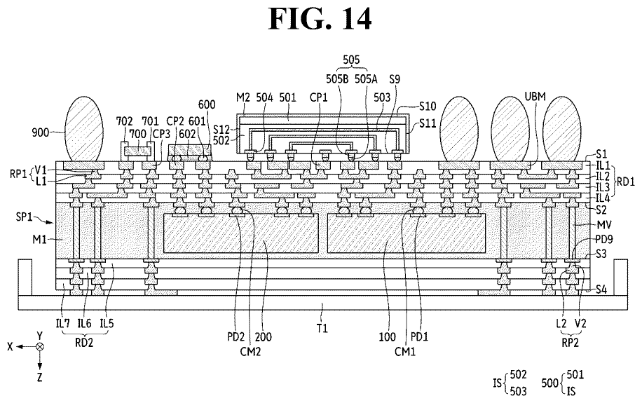

Referring to FIG. 5 and FIG. 14, the bridge die 500 at least partially covered by the second mold film M2 may be bonded to the first redistribution layer RD1 (S112). A reflow process may be performed to electrically connect the bridge die 500 and the connecting terminals 900 to the first redistribution layer RD1 (S113). That is, the bridge die 500 may be attached onto the first face S1 of the first redistribution layer RD1 such that the connecting terminals 900 attached to the connecting pads 504 disposed on the nineth face S9 of the bridge die 500 come into contact with the first connecting patterns CP1 inside the first redistribution insulating film IL1, and the bridge die 500 and the first redistribution layer RD1 may be electrically connected to each other by applying heat to the structure between the bridge die 500 and the first redistribution layer RD1. In an embodiment, the connecting members 505 of the bridge die 500 may be disposed between the connecting pads 504 and the first connecting patterns CP1 of the first redistribution insulating film IL1.

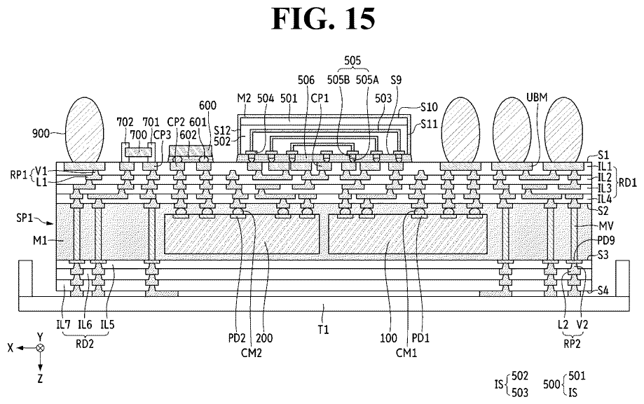

Referring to FIG. 5 and FIG. 15, a first underfill film 506 may be formed between the bridge die 500 and the first redistribution layer RD1 (S114). The material of the first underfill film 506 is filled between the bridge die 500 and the first redistribution layer RD1 such that the material of the first underfill film 506 covers the nineth face S9 of the bridge die 500, the first face S1 of the first redistribution layer RD1, and the connecting members 505. The first underfill film 506 may be hardened to fix the bridge die 500 onto the first redistribution layer RD1.

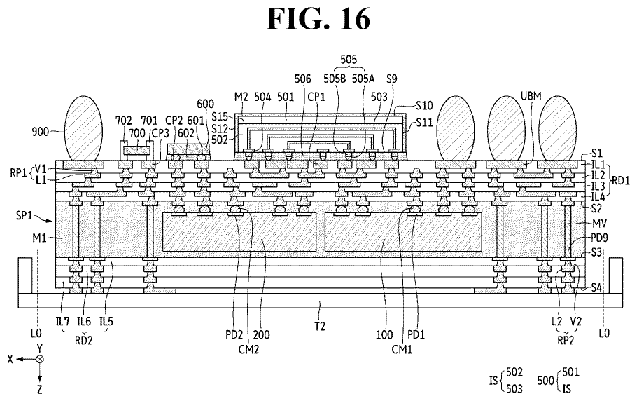

Referring to FIG. 5 and FIG. 16, the heat-resistant tape T1 may be changed to a dicing tape T2 (S115). In some embodiments, the dicing tape T2 is a tape for fixing the semiconductor package configuration and materials attached to the dicing tape T2 when performing a sawing process later, and may not include a heat-resistant material, unlike the heat-resistant tape T1. The sawing process may be performed to separate the semiconductor chips, thereby forming a plurality of first sub-semiconductor packages SP1 (S116).

For example, referring to FIG. 16, the sawing process may be performed along the lines L0 to separate the semiconductor chips, thereby separating the first sub-semiconductor package SP1 that includes the first redistribution layer RD1, the second redistribution layer RD2, the first and second semiconductor chips 100 and 200, the plurality of molding vias MV, the first mold film M1, the passive elements 600 and 700, the bridge die 500, and the connecting terminals 900.

Although one first sub-semiconductor package SP1 is shown in FIG. 16, a plurality of first sub-semiconductor packages SP1 may be provided in the form being attached to the dicing tape T2 in an actual process, and the plurality of first sub-semiconductor packages SP1 may be sawed with the line L0 as the boundary and separated from each other. For example, each first sub-semiconductor package of the plurality of first sub-semiconductor packages SP1 may have the same configuration as shown in FIG. 16.

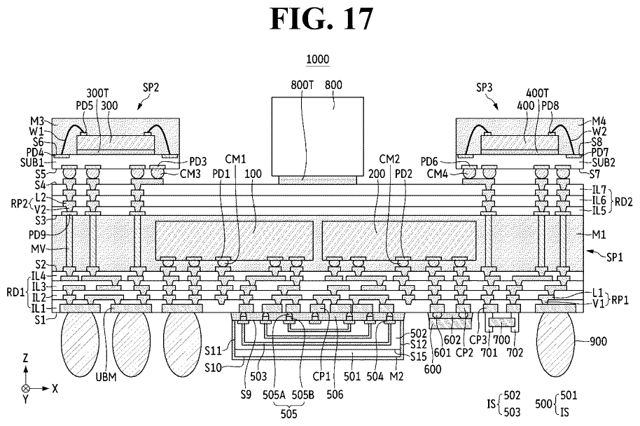

Referring to FIG. 5 and FIG. 17, the second sub-semiconductor package SP2, the third sub-semiconductor package SP3, and the HPB 800 may be mounted on the first sub-semiconductor package SP1 (S117). The second sub-semiconductor package SP2 and the third sub-semiconductor package SP3 may be stacked on the first sub-semiconductor package SP1 such that the first wiring portion L1 on the fourth face S4 of the second redistribution layer RD2, the third connecting members CM3 and the fourth connecting members CM4 are electrically connected to each other. Also, the HPB 800 may be disposed in a portion of the fourth face S4 of the second redistribution layer RD2 spaced apart from the second wiring portion L2.

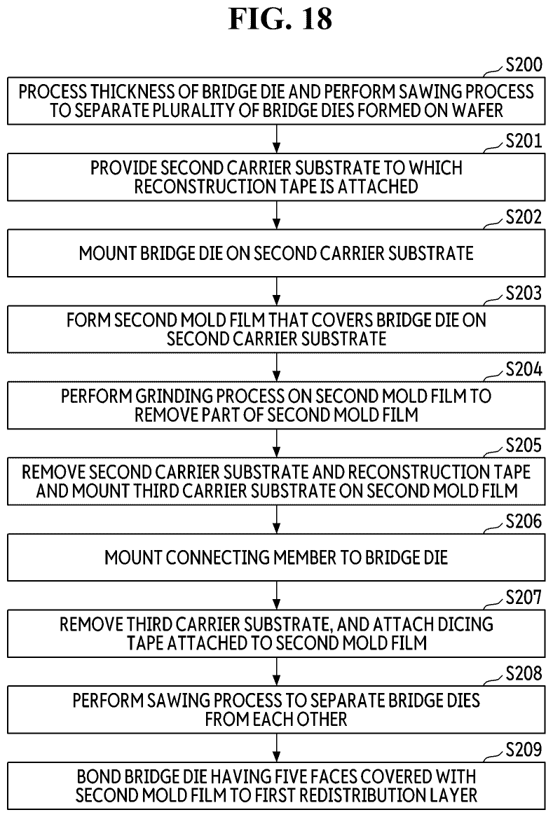

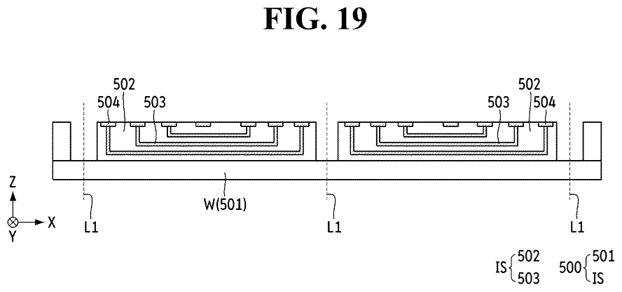

FIG. 18 is a flow chart for explaining a method for providing a bridge die covered with the mold film according to some embodiments. FIGS. 19 to 26 are intermediate stage diagrams for explaining a method for providing a bridge die covered with the mold film according to some embodiments. Hereinafter, a method for providing the bridge die covered with the mold film according to some embodiments will be described referring to FIGS. 18 to 26.

Referring to FIG. 18 and FIG. 19, after processing the thickness of the bridge die 500, the sawing process may be performed to separate the plurality of bridge dies 500 formed on the wafer W from each other (S200). For example, as shown in FIG. 19, the plurality of bridge dies 500 may be formed on the wafer W. The wafer W may be a substrate 501 of the bridge die 500 when the bridge die 500. Before sawing the plurality of bridge dies 500 with the line L1 as the boundary, the thickness in the first direction Z of each bridge die 500 may be processed. The plurality of bridge dies 500 may be sawed with the line L1 as the boundary and separated from each other.

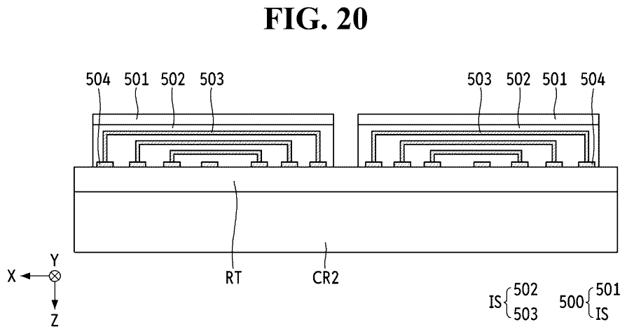

Referring to FIG. 18 and FIG. 20, a second carrier substrate CR2 to which a reconstruction tape RT is attached may be provided (S201), and the bridge die 500 may be mounted on the second carrier substrate CR2 (S202). The second carrier substrate CR2 may include, but not limited to, silicon, metal, glass, plastic, or ceramic. The second carrier substrate CR2 may be used to support a material when forming the bridge die 500, and optionally, may be removed later.

The reconstruction tape RT may be conformally formed on the second carrier substrate CR2. The reconstruction tape RT may abut on the second carrier substrate CR2.

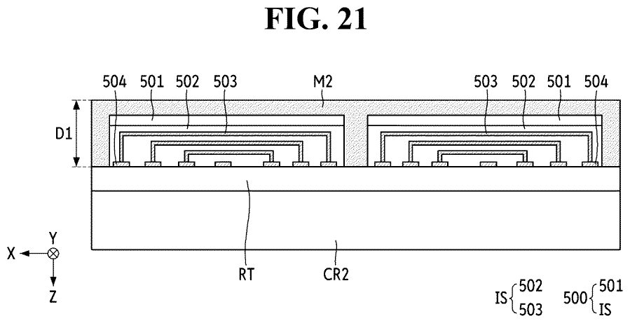

Referring to FIG. 18 and FIG. 21, the second mold film M2 that covers the bridge die 500 may be formed on the second carrier substrate CR2 (S203). In this case, the second mold film M2 may completely cover the reconstruction tape RT and the bridge die 500.

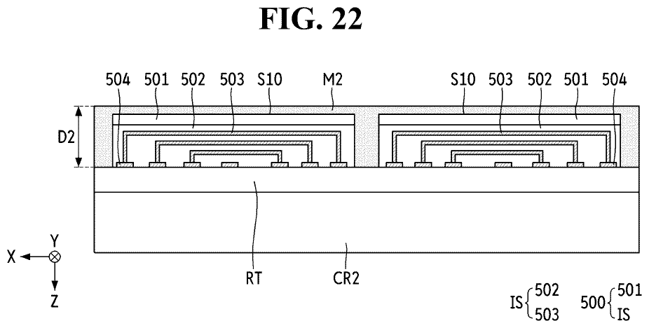

Referring to FIG. 18 and FIG. 22, a grinding process may be performed on the second mold film M2 to remove a part of the second mold film M2 (S204). For example, if the length of the second mold film M2 in the first direction Z before grinding was D1 (shown in FIG. 21), the length of the second mold film M2 in the first direction Z after grinding may be D2, which is smaller than D1. In a case that at least a part of the upper part of the second mold film M2 is ground, a part of the second mold film M2 that covers the face S10 of the bridge die 500 may be removed. However, the second mold film M2 that covers the face S10 of the bridge die 500 may not be completely ground. Accordingly, the tenth face S10 of the bridge die 500 may not be exposed to the outside. The grinding process to remove a part of the second mold film M2 (S204) may be omitted and a method may continue to step S205 with the second mold film M2 having a full height.

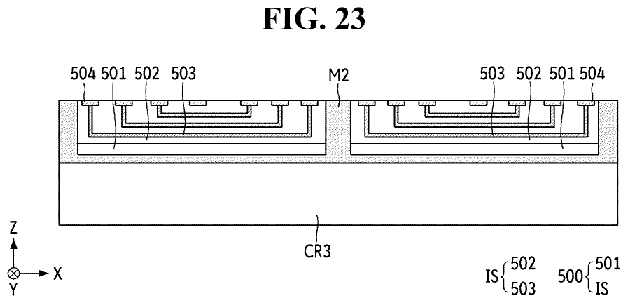

Referring to FIG. 18 and FIG. 23, the bridge die 500 may be turned upside down, and then the third carrier substrate CR3 may be mounted on the second mold film M2 (S205). At this time, the second carrier substrate CR2 may be removed from the bridge die 500. For example, the bridge die 500 wrapped by the second mold film M2 may be mounted on the third carrier substrate CR3 such that the lower face of the second mold film M2 comes into contact with the upper face of the third carrier substrate CR3. The third carrier substrate CR3 may include, but not limited to, silicon, metal, glass, plastic, or ceramic. The third carrier substrate CR3 may be used to support the material when forming the bridge die 500, and optionally, may be removed later.

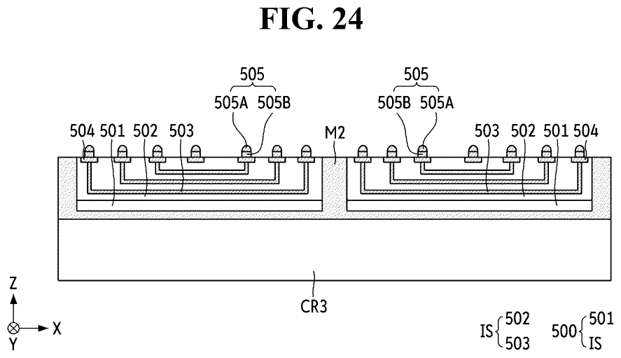

Referring to FIG. 18 and FIG. 24, the connecting members 505 may be attached to the bridge die 500 (S206). For example, a pillar part 505B may be formed on the upper face of the bridge die 500 to abut on the connecting pad 504 of the bridge die 500, and a solder part 505A may be formed on the pillar part 505B.

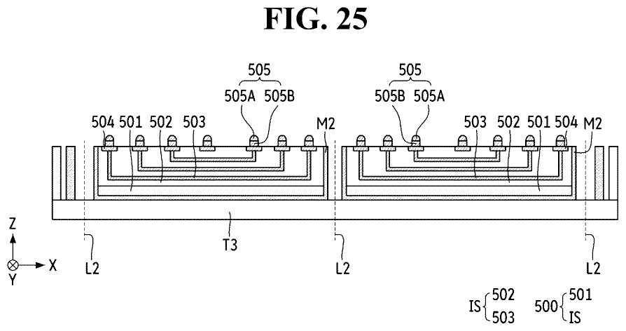

Referring to FIG. 18 and FIG. 25, the third carrier substrate CR3 may be removed, and the dicing tape T3 may be attached to the second mold film M2 (207). Next, the sawing process may be performed to separate the bridge dies 500 from each other (S208). The bridge die 500 manufactured in this way may have five faces including the tenth through fourteenth faces $10, S11, S12, S13, and S14, that may be covered with the second mold film M2. The nineth face S9, corresponding to the upper face, may be exposed by the second mold film M2. In some embodiments, the connecting pads 504 or the connecting members 505 may be exposed by the second mold film M2, and at least a portion of the nineth face S9 may be covered by the second mold film M2.

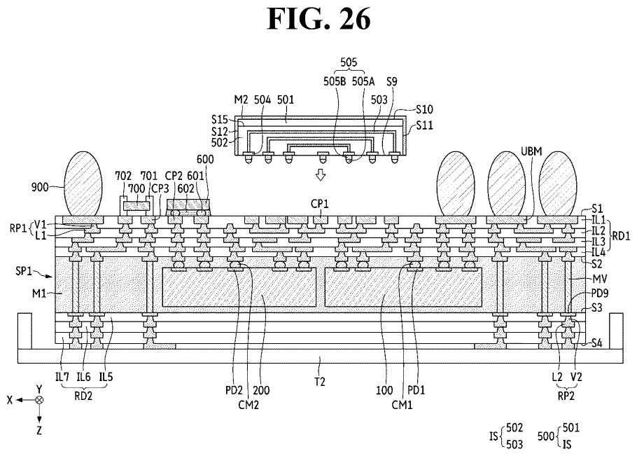

Referring to FIG. 18 and FIG. 26, the bridge die 500 having faces covered with the second mold film M2 may be bonded to the first redistribution layer RD1 (S209). Thereafter, the processes described herein with reference to FIGS. 14 to 17 may be performed, and a semiconductor package 1000 of a POP structure (shown in FIG. 2) may be provided.

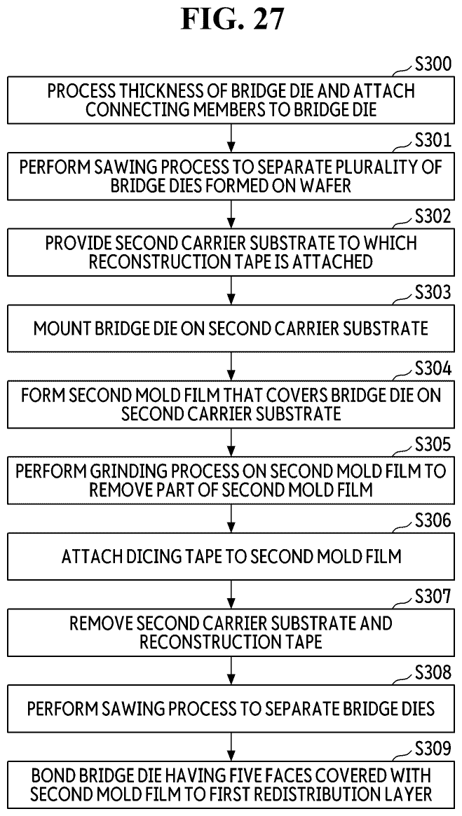

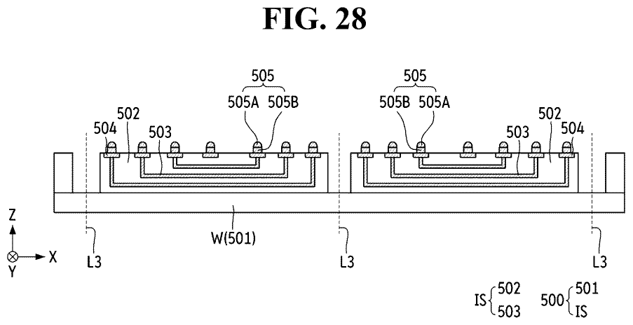

FIG. 27 is a flowchart for explaining a method for manufacturing the bridge die and the mold film according to some embodiments. FIGS. 28 to 35 are intermediate stage diagrams for explaining a method for manufacturing the bridge die and the mold film according to some embodiments. Hereinafter, a method for manufacturing the bridge die and the mold film according to some embodiments will be described with reference to FIGS. 27 to 35. Hereinafter, repeated explanation of elements or features described elsewhere herein may be simplified or omitted, and differences will be mainly described.

Referring to FIG. 27 and FIG. 28, connecting members 505 may be attached to the bridge die 500 after processing the thickness of the bridge die 500 (S300). In an embodiment of a method for manufacturing the bridge die of FIG. 27, the connecting member 505 may be attached to the bridge die 500 before wrapping the bridge die 500 with the second mold film M2.

The sawing process may be formed to separate the plurality of bridge dies 500 formed on the wafer W (S301). For example, the plurality of bridge dies 500 may be by sawed with the line L3 as a boundary, and separated from one another.

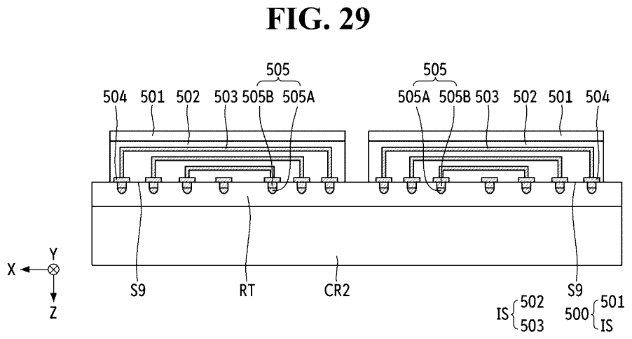

Referring to FIG. 27 and FIG. 29, a second carrier substrate CR2 to which the reconstruction tape RT is attached may be provided (S302), and the bridge die 500 may be mounted onto the second carrier substrate CR2 (S303). The bridge die 500 may be turned upside down and mounted on the second carrier substrate CR2 such that the nineth face S9 of the bridge die 500 comes into contact with the reconstruction tape RT.

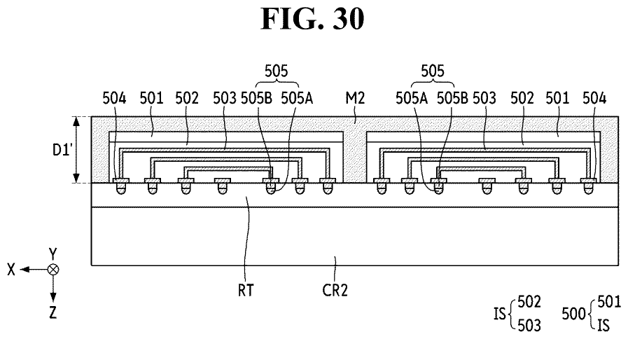

Referring to FIG. 27 and FIG. 30, a second mold film M2 that covers the bridge die 500 may be formed on the second carrier substrate CR2 (S304). In this case, the second mold film M2 may completely cover the reconstruction tape RT and the bridge die 500.

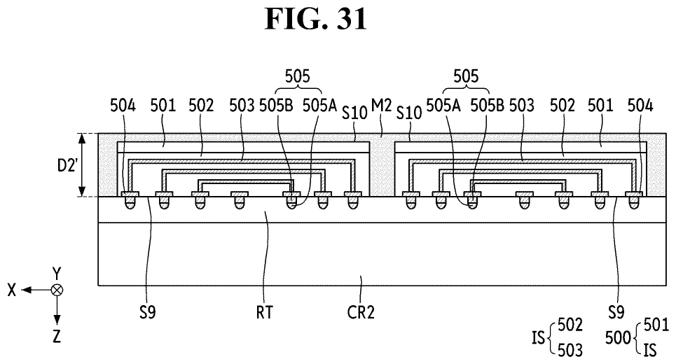

Referring to FIG. 27 and FIG. 31, a grinding process may be performed on the second mold film M2 to remove a part of the second mold film M2 (S305). For example, if the length of the second mold film M2 in the first direction Z before grinding was D1′ (shown in FIG. 30), the length of the second mold film M2 in the first direction Z after grinding may be D2′ which is smaller than D1′. As at least a part of the upper part of the second mold film M2 is ground, a part of the second mold film M2 that covers the tenth face S10 of the bridge die 500 may be removed. However, the second mold film M2 that covers the tenth face S10 of the bridge die 500 may not be completely removed. Accordingly, the tenth face S10 of the bridge dies 500 may not be exposed to the outside.

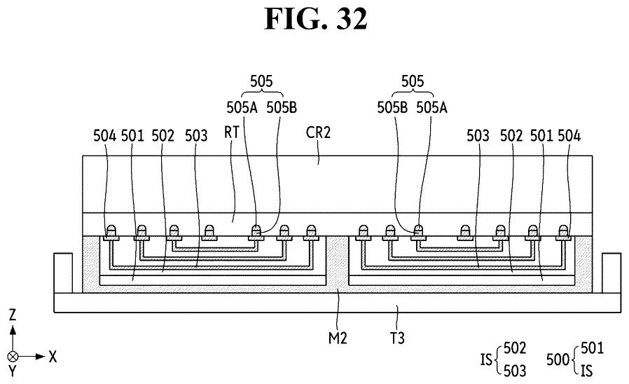

Referring to FIG. 27 and FIG. 32, the bridge die 500 covered with the second mold film M2 and the second carrier substrate CR2 may be turned upside down, and the dicing tape T3 may be attached to the second mold film M2 (S306).

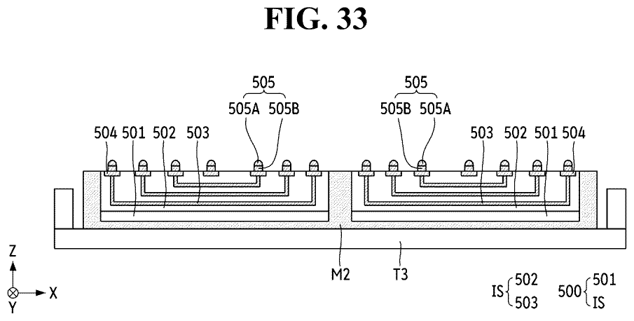

Referring to FIG. 27 and FIG. 33, the second carrier substrate CR2 and the reconstruction tape RT may be removed from the bridge dies 500 covered with the second mold film M2 (S307).

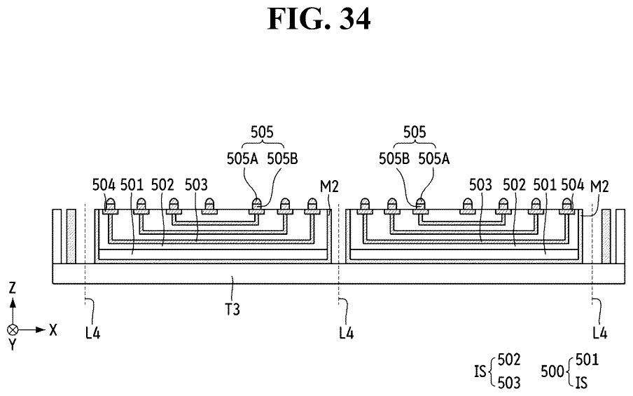

Referring to FIG. 27 and FIG. 34, the bridge dies 500 may be separated by performing the sawing process (S308). For example, the plurality of bridge dies 500 may be sawed with the line L4 as the boundary, and separated from each other. The bridge die 500 manufactured in this way may have five faces including the tenth through fourteenth faces S10, S11, S12, S13, and S14 covered with the second mold film M2. The nineth face S9 may not be covered with the second mold film M2.

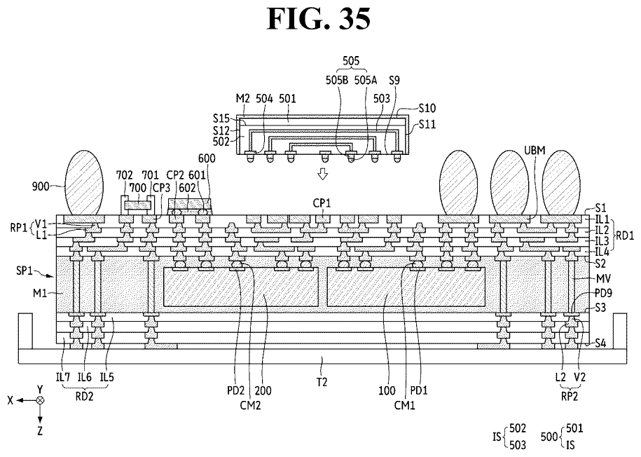

Referring to FIG. 27 and FIG. 35, the bridge die 500 having a plurality of faces covered with the second mold film M2 may be bonded to the first redistribution layer RD1 (S309). The subsequent processes described herein with reference to FIGS. 14 to 17 may be performed, and the semiconductor package 1000 may be manufactured (shown in FIG. 2).

Although embodiments of the present disclosure have been described with reference to the accompanying drawings, the present disclosure is not limited to embodiments described herein, but may be implemented in various different forms. A person skilled in the art may appreciate that the present disclosure may be practiced in other concrete forms without changing the technical spirit or essential characteristics of the present disclosure. Therefore, it should be appreciated that embodiments as described herein are not restrictive but illustrative in all respects.

What is claimed is:

1. A semiconductor package comprising:
a first redistribution layer which includes a first face and a second face that are opposite to each other in a first direction;
a first semiconductor chip on the second face of the first redistribution layer;
a second semiconductor chip on the second face of the first redistribution layer;
a first mold film on the second face of the first redistribution layer, and that covers the first semiconductor chip and the second semiconductor chip; and
a bridge die disposed on the first face of the first redistribution layer, and that electrically connects the first semiconductor chip and the second semiconductor chip,
wherein the bridge die is covered with a second mold film.

2. The semiconductor package of claim 1, further comprising:
a plurality of molding vias on the second face to be spaced apart from the first semiconductor chip and the second semiconductor chip,
wherein the first mold film on the second face of the first redistribution layer covers the plurality of molding vias; and
a second redistribution layer disposed on the first mold film and electrically connected to the plurality of molding vias,
wherein each of the plurality of molding vias extends in the first direction, and is disposed to surround the first semiconductor chip and the second semiconductor chip.

3. The semiconductor package of claim 1, further comprising:
a first connecting member between the first semiconductor chip and the first redistribution layer; and
a second connecting member between the second semiconductor chip and the first redistribution layer,
wherein the bridge die electrically connects the first connecting member and the second connecting member.

4. The semiconductor package of claim 1, wherein the bridge die comprises:
a third face that faces the first face;
a fourth face that is opposite to the third face in the first direction;
a fifth face and a sixth face that are opposite to each other in a second direction intersecting the first direction; and
a seventh face and an eighth face that are opposite to each other in a third direction intersecting the first direction and the second direction,
wherein the fourth face to the eighth face are covered with the second mold film.

5. The semiconductor package of claim 4, wherein the bridge die comprises:
a dielectric layer; and
a substrate disposed on the dielectric layer,
wherein the substrate forms the fourth face of the bridge die.

6. The semiconductor package of claim 1, further comprising:
an underfill film disposed between the bridge die and the first redistribution layer,
wherein the second mold film is disposed on the underfill film.

7. The semiconductor package of claim 2,
wherein the second redistribution layer includes a nineth face that faces the first semiconductor chip, and a tenth face that is opposite to the nineth face in the first direction, and
the second redistribution layer includes a first wiring portion on the tenth face, and
the semiconductor package further comprises:
a package substrate disposed on the second redistribution layer;
a third semiconductor chip on the package substrate; and
a first connecting member between the package substrate and first wiring portion of the second redistribution layer.

8. The semiconductor package of claim 7,
wherein the first connecting member is provided as a plurality of first connecting members, and
the first connecting members connect the first wiring portion and a connecting pad of the package substrate.

9. The semiconductor package of claim 7, further comprising:
a heat path block (HPB) disposed on the tenth face at a location spaced apart from the first wiring portion; and
at least one passive element disposed on the first face.

10. A semiconductor package comprising:
a first redistribution layer which includes a first face and a second face that are opposite each other in a first direction;
a second redistribution layer which is disposed apart from the first redistribution layer in the first direction, and includes a third face that faces the second face, and a fourth face that is opposite to the third face from each other in the first direction;
a first semiconductor chip and a second semiconductor chip disposed between the first redistribution layer and the second redistribution layer;
a plurality of molding vias disposed between the first redistribution layer and the second redistribution layer and that extend in the first direction;
a first sub-semiconductor package disposed on the second redistribution layer; and
a bridge die disposed on the first face, and that electrically connects the first semiconductor chip and the second semiconductor chip,
wherein at least a part of a surface of the bridge die is covered with a mold film.

11. The semiconductor package of claim 10,
wherein the bridge die includes
a fifth face which faces the first face,
a sixth face which is opposite to the fifth face in the first direction;
a seventh face and a eighth face which are opposite to each other in a second direction intersecting the first direction; and
a nineth face and a tenth face which are opposite to each other in a third direction intersecting the first direction and the second direction,
wherein the sixth face to the tenth face are covered with the mold film.

12. The semiconductor package of claim 11, wherein the bridge die comprises:
a plurality of connecting pads exposed on the fifth face of the bridge die;
a plurality of metal lines electrically connected to the plurality of connecting pads, wherein the plurality of metal lines and the plurality of connecting pads electrically connect the first semiconductor chip and the second semiconductor chip;
a dielectric layer surrounding the plurality of metal lines; and
a substrate disposed on the dielectric layer that forms the sixth face of the bridge die.

13. The semiconductor package of claim 12, further comprising a connecting member disposed between the bridge die and the first redistribution layer,
wherein the connecting member includes a plurality of pillar parts that abut on the plurality of connecting pads and a plurality of solder parts that connect the plurality of pillar parts to the first redistribution layer.

14. The semiconductor package of claim 13, further comprising:
an underfill film between the bridge die and the first redistribution layer,
wherein the underfill film covers the connecting member.

15. The semiconductor package of claim 10, further comprising a plurality of connecting terminals disposed on the first face of the first redistribution layer, wherein the bridge die is at least partially surrounded by the plurality of connecting terminals.

16. A semiconductor package comprising:
a first redistribution layer which includes a first face and a second face that are opposite to each other in a first direction;
a first semiconductor chip on the second face of the first redistribution layer;
a second semiconductor chip on the second face of the first redistribution layer;
a first mold film on the second face of the first redistribution layer, and that covers the first semiconductor chip and the second semiconductor chip;
and
a bridge die disposed on the first face of the first redistribution layer, and that electrically connects the first semiconductor chip and the second semiconductor chip,
wherein the bridge die includes:
a third face that faces the first face;
a fourth face that is opposite to the third face in the first direction;
a fifth face and a sixth face that are opposite to each other in the second direction; and
a seventh face and an eighth face that are opposite to each other in a third direction intersecting the first direction and the second direction; and
wherein the fourth face to the eighth face is covered with a second mold film.

17. The semiconductor package of claim 16, further comprising:
a first connecting member between the first semiconductor chip and the first redistribution layer; and
a second connecting member between the second semiconductor chip and the first redistribution layer,
wherein the bridge die electrically connects the first connecting member and the second connecting member.

18. The semiconductor package of claim 17,
wherein the first mold film covers the first connecting member and the second connecting member, and fills a gap between the first semiconductor chip and the first redistribution layer, and a gap between the second semiconductor chip and the first redistribution layer.

19. The semiconductor package of claim 16, further comprising:
a second redistribution layer on the first mold film,
wherein the second redistribution layer includes a ninth face that faces the first semiconductor chip, and a tenth face that is opposite to the ninth face in the first direction, and
the second redistribution layer includes a first wiring portion on the tenth face.

20. The semiconductor package of claim 16, further comprising:
at least one passive element on the first face.
